(19) United States
(12) Patent Application Publication
(10) Pub. No.: US 2024/0037287 A1
(43) Pub. Date: Feb. 1, 2024

(54) SYSTEM AND METHODS EMBODYING THE CALORIBRATE© CONCEPT AND THE CALORIBRATION RATING© PROCESS

(71) Applicants: Ganapathy Mahalingam, Fargo, ND (US); Claire Elise Olson, Fargo, ND (US)

(72) Inventors: Ganapathy Mahalingam, Fargo, ND (US); Claire Elise Olson, Fargo, ND (US)

(21) Appl. No.: 18/228,457

(22) Filed: Jul. 31, 2023

Related U.S. Application Data
(60) Provisional application No. 63/394,051, filed on Aug. 1, 2022.

(51) Int. Cl. G06F 30/13

(52) U.S. Cl. CPC G06F 30/13

(57) ABSTRACT

Caloribrate@ is a term that can be used in connection with the system and methods disclosed herein, which in some embodiments involves calibrating a building by measuring the physical activity of its inhabitants using biosensing equipment such as activity monitors commercialized under trademarks such as FITBIT®, GARMIN®, APPLE®, OURA®, and WHOOP®. All movements of subjects can be mapped in a physical zone (e.g., building), and the calories consumed, and heartbeats expended in making those movements can be calculated. Then a measure is derived to arrive at a physical zone (e.g., building) rating based on the Caloribrate@ concept and a Caloribration Rating@ process, which can be used to classify physical zones (e.g., buildings) based on how well they support physical activity. This can be used as a predictive tool that indicates the potential for physical activity in a building, thereby indicating its viability to make subjects healthier.

### CROSS-REFERENCE TO RELATED APPLICATIONS

This application claims priority to U.S. Provisional Application Ser. No. 63/394,051, titled, METHOD AND SYSTEM FOR PREDICTING LIKELIHOOD FOR HEALTH AND/OR HEALTHY BEHAVIOR OF SUBJECTS IN A PHYSICAL ZONE USING DATA FROM BIOSENSING EQUIPMENT, filed on Aug. 1, 2022, incorporated by reference herein in its entirety. The intellectual property rights to the application referenced above were transferred back to the inventors on Jun. 14, 2023, by the NDSU Research Foundation, which was the assignee of the said intellectual property rights and had filed the provisional application referred to above.

### FEDERALLY SPONSORED RESEARCH AND DEVELOPMENT

The invention described in this application was developed with federal funds provided through a grant from the National Institutes of Health under grant No. P20 GM 103442 and documented in a National Institutes of Health invention report with EIR No. 6091701-22-0007. The National Institutes of Health may hold rights to the invention disclosed herein.

### PRIOR ART

The invention disclosed herein was publicly disclosed for the first time using a research poster on Aug. 5, 2022. The research poster is included in this application as FIG. 1. Two other research posters with subsequent reductions to practice of the invention disclosed herein, were submitted to the National Institutes of Health as part of grant reporting requirements. These research posters are also included in this application as FIG. 2 and FIG. 3. Numerical ratings of physical zones to indicate their potential for promoting health and wellness have been developed in other forms, by institutions such as the International Well Building Institute and the International Living Future Institute. These two institutes have developed the WELL Building Standard and the Living Building Challenge standards respectively. The invention disclosed herein comprises an original set of processes that has no precedent in the prior art embodied in the standards referenced above.

### BACKGROUND OF THE INVENTION

The subject matter disclosed herein generally relates to evaluating, designing, constructing, and operating buildings and other physical zones. The subject matter disclosed herein also relates to the rating of buildings and other physical zones for their performance in facilitating health and wellness. Certain embodiments of the subject matter disclosed herein relate to predicting the likelihood for health and/or healthy behavior of subjects in buildings and other physical zones using biosensing equipment. Examples of physical zones include buildings and defined geographical areas, such as, for example, a neighborhood, a city block, a park, a city, or a state.

### SUMMARY OF THE INVENTION

Caloribrate@ is a term that can be used in connection with the system and methods disclosed herein, which in some embodiments involves calibrating a building by measuring the physical activity of its inhabitants using biosensing equipment such as activity monitors commercialized under trademarks such as FITBIT®, GARMIN®, APPLE®, OURA®, and WHOOP®. All movements of subjects can be mapped in a physical zone (e.g., building), and the calories consumed, and heartbeats expended in making those movements can be calculated. Then a measure is derived to arrive at a physical zone (e.g., building) rating based on the Caloribrate@ concept and a Caloribration Rating@ process, which can be used to classify physical zones (e.g., buildings) based on how well they support physical activity. This can be used as a predictive tool that indicates the potential for physical activity in a building, thereby indicating its viability to make subjects healthier.

### BRIEF DESCRIPTION OF DRAWINGS

For the invention disclosed herein to be easily understood and readily practiced, the invention will be described, for the purposes of illustration and not limitation, in conjunction with the following figures, wherein:

FIG. 1 describes the calibration process of Renaissance Hall in Fargo, North Dakota, which is the subject matter of the invention disclosed herein. This process was publicly disclosed for the first time using this research poster on Aug. 5, 2022.

FIG. 2 describes the calibration process of Renaissance Hall in Fargo, North Dakota, conducted during a different time of the year to record the seasonal variations in the calibration.

FIG. 3 describes the calibration of Klai Hall in Fargo, North Dakota, in order to use the calibration methods to compare the performance of two different buildings.

FIG. 4 depicts a flow chart of the methodology that comprises the Caloribrate@ process, which is the subject matter of the invention disclosed herein.

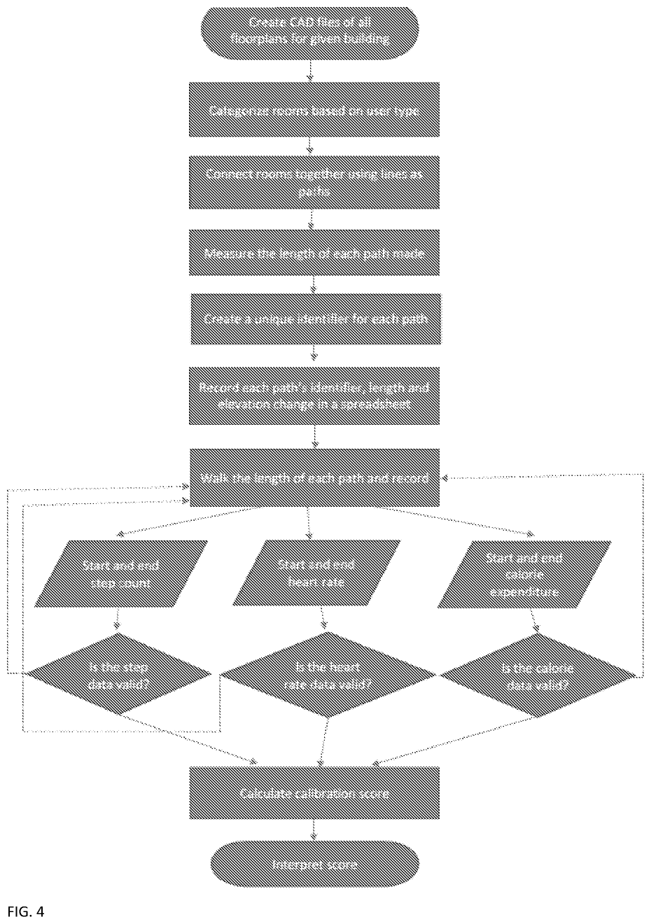

FIG. 5 depicts a flow chart of the methodology to arrive at the rating of the physical zone using the Caloribrate Rating@ process.

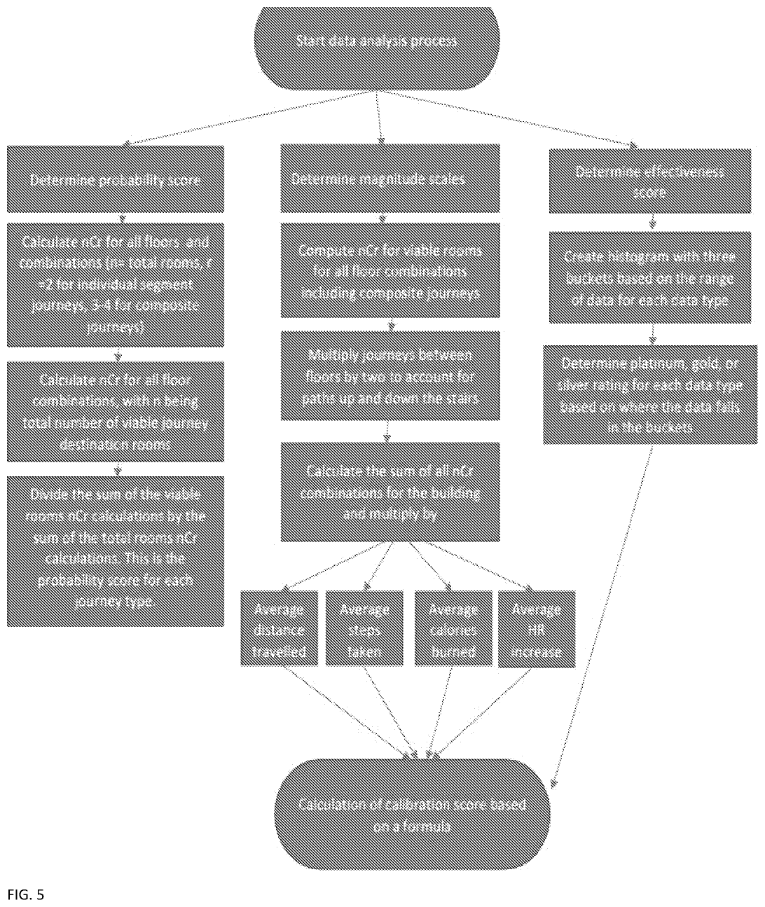

FIG. 6 depicts the floor plan of the Basement of Klai Hall with viable journeys mapped onto the floor plans using color-coded lines for the various types of inhabitants of the building.

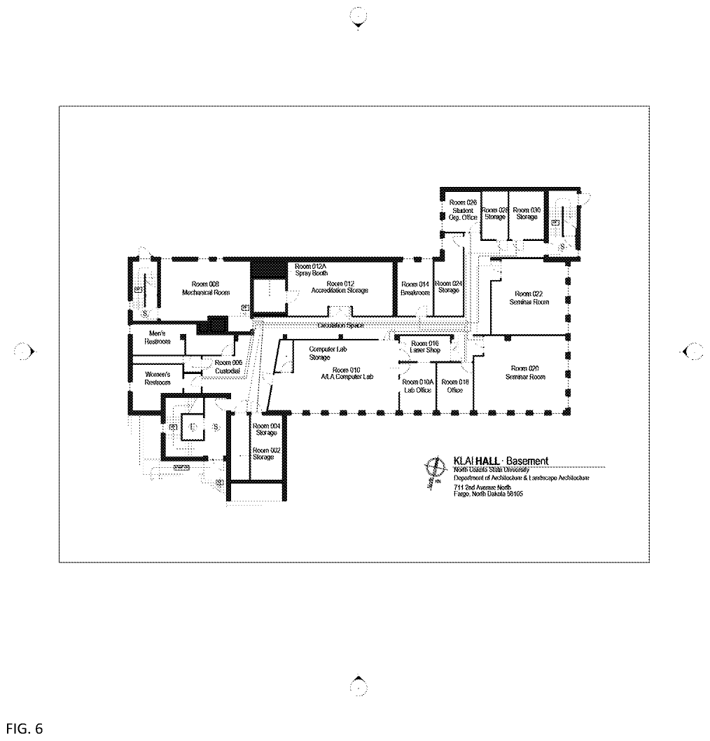

FIG. 7 depicts the floor plan of the 1^{st} floor of Klai Hall with viable journeys mapped onto the floor plans using color-coded lines for the various types of inhabitants of the building.

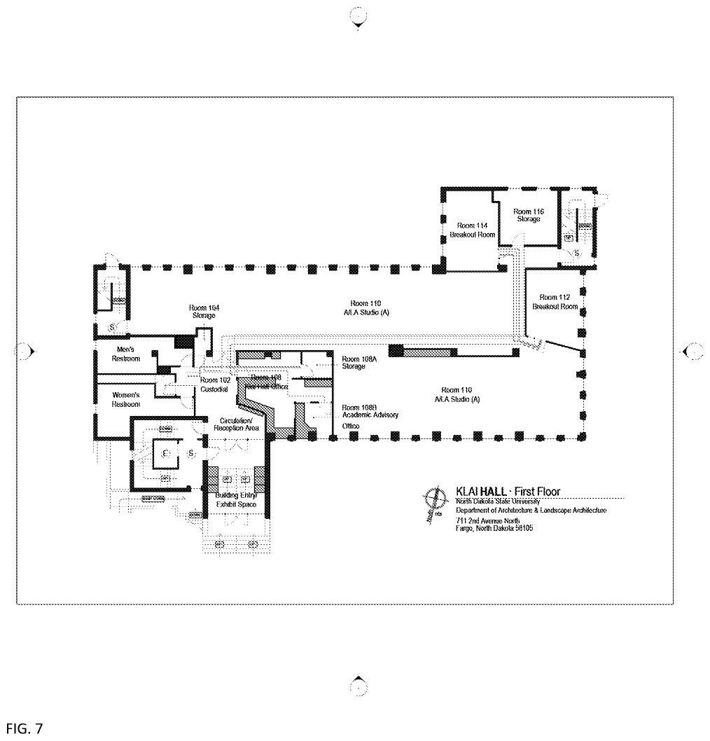

FIG. 8 depicts the floor plan of the 2nd floor of Klai Hall with viable journeys mapped onto the floor plans using color-coded lines for the various types of inhabitants of the building.

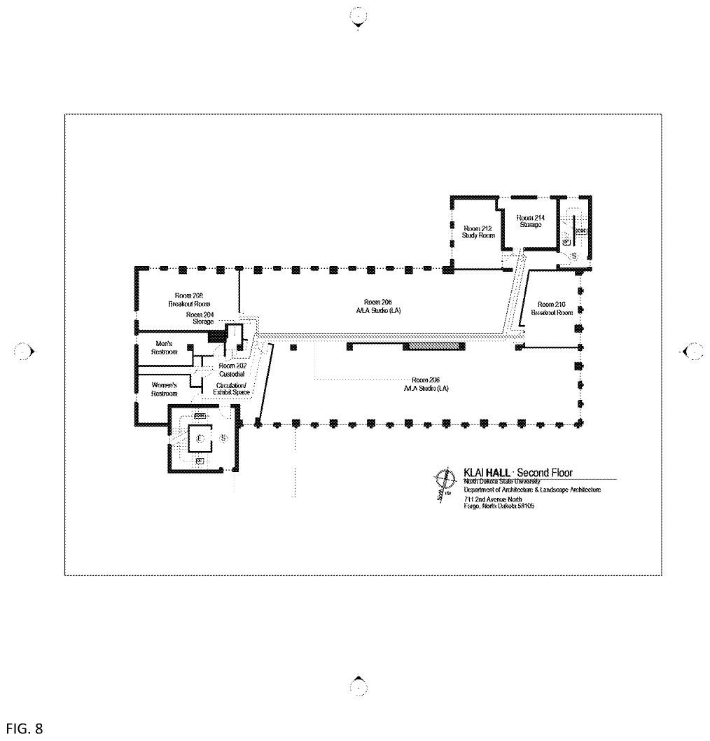

FIG. 9 depicts the floor plan of the 3rd floor of Klai Hall with viable journeys mapped onto the floor plans using color-coded lines for the various types of inhabitants of the building.

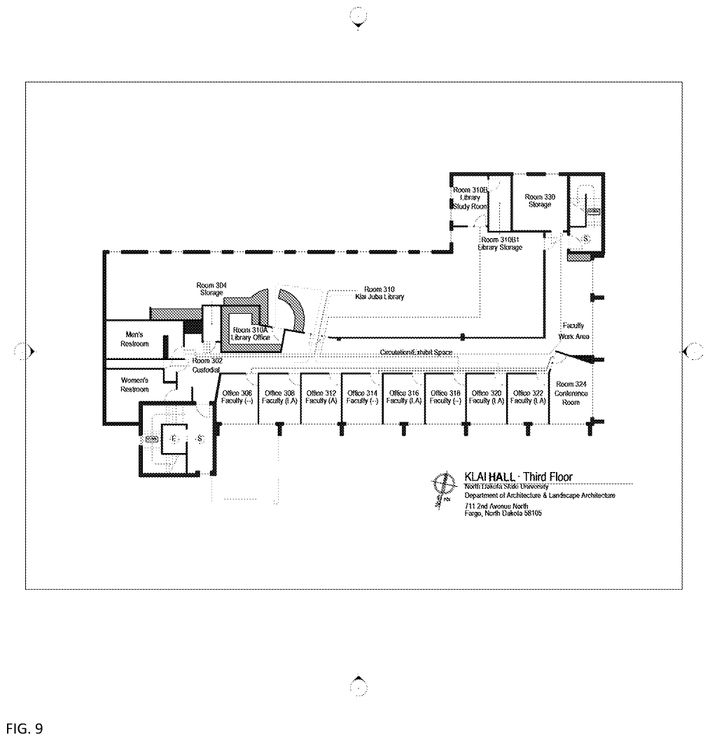

FIG. 10 shows the biophysical data collected from a subject using biosensing equipment as the subject made the various journeys depicted in the floor plans of Klai Hall.

FIG. 11 shows the calculations performed to arrive at the probability score used in the final rating of the physical zone, namely Klai Hall, using the Caloribration Rating@ process.

### DETAILED DESCRIPTION OF THE INVENTION

The details of one or more embodiments of the invention disclosed herein are set forth in this document. Modifications to embodiments described in this document, and other embodiments, will be evident to those of ordinary skill in the art after a study of the information provided in this document. The information provided in this document, and particularly the specific details of the described exemplary embodiments, is provided primarily for clearness of understanding and no unnecessary limitations are to be understood therefrom. In case of conflict, the specification of this document, including definitions, will control.

Caloribrate@ is a term that can be used in connection with the methods and systems disclosed herein, which in some embodiments involves calibrating a building by measuring the physical activity of its inhabitants using biosensing equipment such as activity monitors commercialized under trademarks such as FITBIT®, GARMIN®, APPLE®, OURA®, and WHOOP®. All movements of subjects can be mapped in a physical zone (e.g., building), and the calories consumed, and heartbeats expended in making those movements can be calculated. Then a measure is derived to arrive at a physical zone (e.g., building) rating based on the Caloribrate@ concept and a Caloribration Rating@ process, which can be used to classify physical zones (e.g., buildings) based on how well they support physical activity. This can be used as a predictive tool that indicates the potential for physical activity in a building, thereby indicating its viability to make subjects healthier.

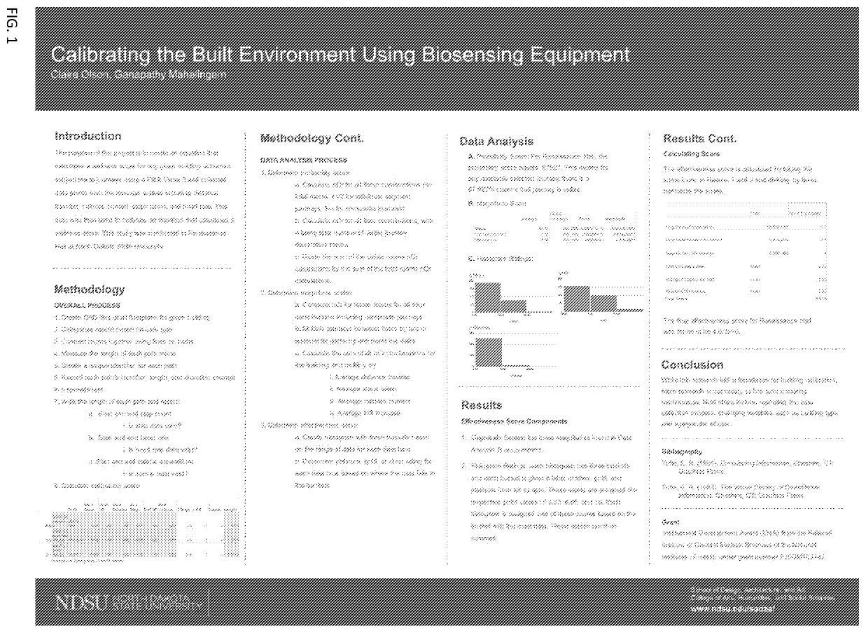

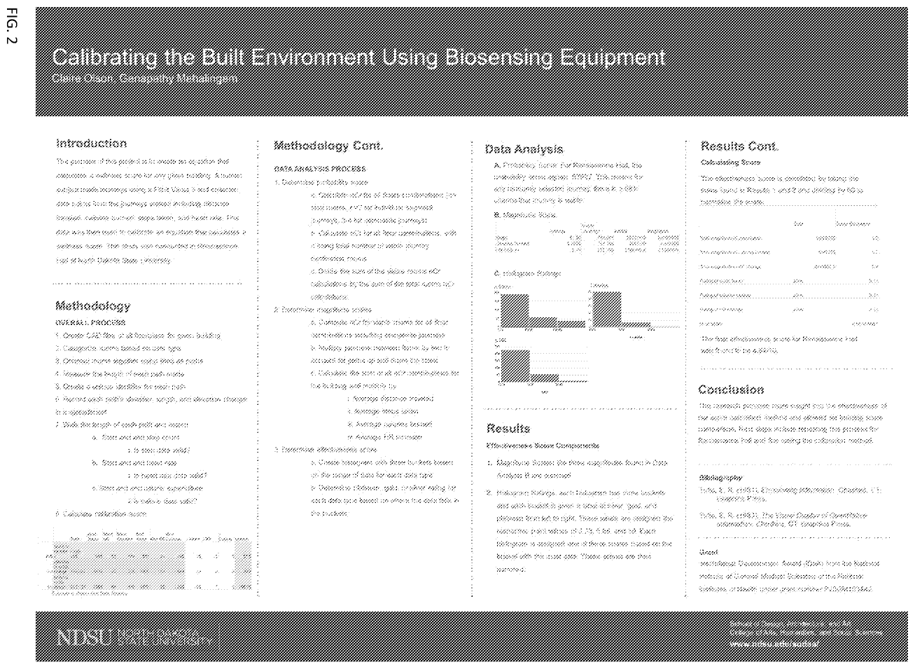

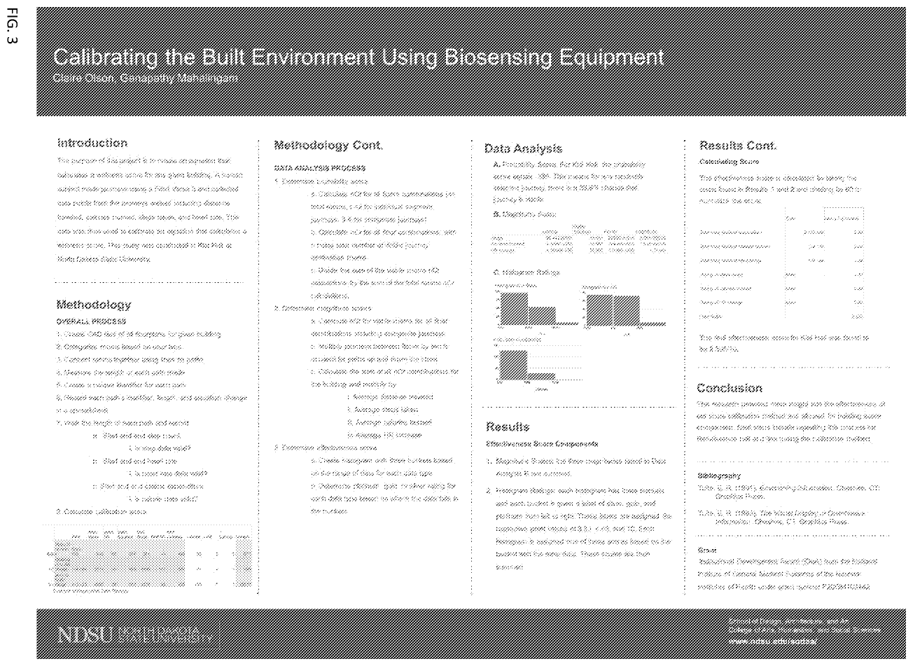

The invention disclosed herein comprises a system with four integrated methods. The four methods are (a) A method that is used to extract information about the physical features of a physical zone; (b) A method that is used to measure the biophysical responses of subjects inhabiting the physical zone using biosensing equipment; (c) A method that is used to analyze and process the measurements made in method (b); and (d) A method that is used to calibrate the physical zone with a numerical rating using the data in method (c). These four integrated methods are described in detail in FIG. 1, FIG. 2, and FIG. 3. In addition, a detailed description of the system and its methods is described as a step-by-step process in Appendix A, which is included in this application.

The four methods referenced in [0020] are grouped into three phases: (a) data gathering; (b) data analysis; and (c) performance rating.

The data-gathering phase of the calibration of a physical zone referenced in [0021] begins with the creation of a set of descriptive representations of the physical zone in the form of dimensioned drawings, which may be created in an analog or digital medium.

The next step that follows [0022] is to map various activities of inhabitants of the physical zone in the representations of the physical zones, for example, the various journeys that can be performed in the physical zone can be mapped on the dimensioned drawings. The journeys are represented with color-coded lines to identify the type of inhabitant making the journey.

The next step that follows [0023] is to measure the various paths for the journeys mapped in the dimensioned drawings and record the distances for the journeys, keeping in mind that journeys can continue onto another floor by utilizing a staircase or an elevator.

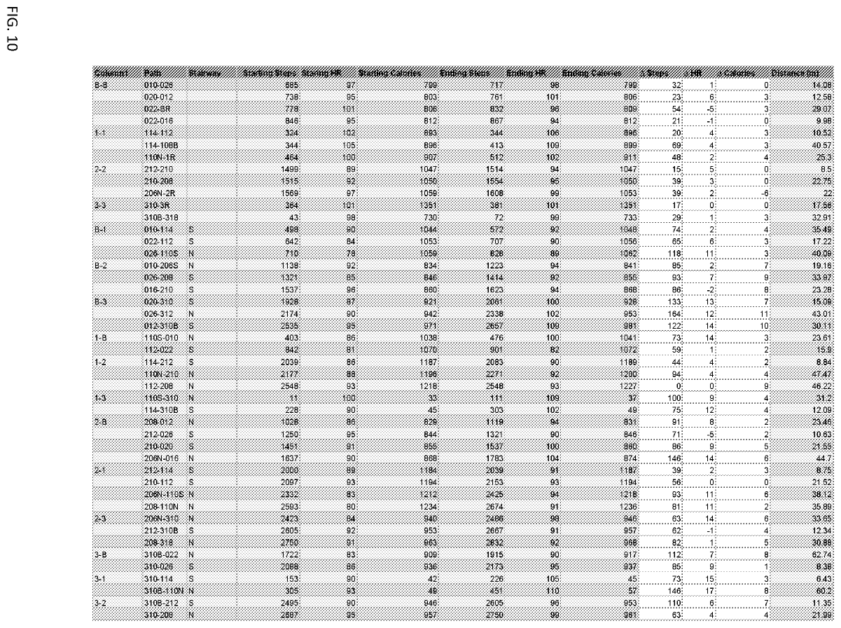

The next step that follows [0024] is for a subject to walk those paths and record their biophysical responses using wearable biosensing equipment. Biophysical responses are physical quantities related to a functioning human body and are recorded as temperature, blood pressure, energy consumed (calories), steps taken (distance traveled), and heart rate (which is a frequency). The biophysical responses of subjects that are recorded using the biosensing equipment are tabulated in a spreadsheet in order to calculate summary measurements such as averages and totals. An example of the tabulation of data collected from a subject in a physical zone is shown in FIG. 10.

The data-analysis phase referenced in [0021] begins with the calculation of the average data for the calories burned, steps taken, and changes in heart rate, considering all the sample journeys made by a subject. There are three scores to be computed in this phase: (a) the Probability score, (b) the Magnitude score, and (c) the Effectiveness score.

The performance-rating phase takes the scores derived in the data-analysis phase referenced in [0021] and uses a formula to compute a final numerical rating for the physical zone.

The invention disclosed herein includes methods for predicting the likelihood for the health of a subject in a physical zone, which involves the steps of determining a probability score as disclosed herein; determining a magnitude scale as disclosed herein; and determining an effectiveness score as disclosed herein. The invention disclosed herein further includes a system for performing steps of the methods for predicting the likelihood for the health of a subject in a physical zone, as disclosed herein.

Examples of physical zones that can be assessed using the methods and systems as disclosed herein include but are not limited to, a building, a neighborhood, a city block, a park, a city, and a state. Health can be related to overall health, including the behaviors of subjects in the physical zone and environmental factors specific for the physical zone. In some embodiments, health refers to healthy behaviors. In some embodiments, health refers to physical activity.

Additional environmental factors can be used in an assessment. For example, in the case of a physical zone that is a building, additional environmental factors could include indoor air quality and lighting levels. These factors can be incorporated into the Caloribration Rating@ process to make a robust assessment of the viability of a building to improve a subject's health.

Based on this rating, physical zones such as buildings can be identified as more or less healthy to occupy. The rating can be applied when designing or renovating a physical zone such as a building. For example, it could be used to guide the training and work of architects.

While the terms used herein are believed to be well understood by those of ordinary skill in the art, specific definitions are set forth to facilitate an explanation of the subject matter disclosed herein.

Unless defined otherwise, all technical and scientific terms used herein have the same meaning as is commonly understood by one of skill in the art to which the invention(s) belong.

All patents, patent applications, published applications and publications, databases, websites and other published materials referred to throughout the entire disclosure herein, unless noted otherwise, are incorporated by reference in their entirety.

Where reference is made to a URL or other such identifier or address, it is understood that such identifiers can change and particular information on the internet can come and go, but equivalent information can be found by searching the internet. Reference thereto evidences the availability and public dissemination of such information.

Although any methods, devices, and materials similar to or equivalent to those described herein can be used in the practice or testing of the subject matter disclosed herein, representative methods, devices, and materials are described herein.

The present application can “comprise” (open-ended) or “consist essentially of” the components of the present invention as well as other ingredients or elements not described herein. As used herein, “comprising” is open-ended and means the elements recited, or their equivalent in structure or function, plus any other element or elements which are not recited. The terms “having” and “including” are also to be construed as open-ended unless the context suggests otherwise.

Following long-standing patent law convention, the terms “a”, “an”, and “the” refer to “one or more” when used in this application, including the claims. Thus, for example, reference to “a cell” includes a plurality of such cells, and so forth.

Unless otherwise indicated, all numbers expressing quantities of ingredients, properties such as reaction conditions, and so forth used in the specification and claims are to be understood as being modified in all instances by the term “about”. Accordingly, unless indicated to the contrary, the numerical parameters set forth in this specification and claims are approximations that can vary depending upon the desired properties sought to be obtained by the subject matter disclosed herein.

As used herein, the term “about,” when referring to a value or to an amount of mass, weight, time, volume, concentration or percentage is meant to encompass variations of in some embodiments ±20%, in some embodiments ±10%, in some embodiments ±5%, in some embodiments ±1%, in some embodiments ±0.5%, in some embodiments ±0.1%, in some embodiments ±0.01%, and in some embodiments ±0.001% from the specified amount, as such variations are appropriate to perform the disclosed method.

As used herein, ranges can be expressed as from “about” one particular value, and/or to “about” another particular value. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, “optional” or “optionally” means that the subsequently described event or circumstance does or does not occur and that the description includes instances where said event or circumstance occurs and instances where it does not. For example, an optionally variant portion means that the portion is variant or non-variant.

The invention disclosed herein is further illustrated by a specific but non-limiting example. The example may include compilations of data that are representative of data gathered at various times during the course of development and experimentation related to the invention disclosed herein.

### EXAMPLE

Finally, for further explanation of the features, benefits, and advantages of the invention disclosed herein, attached is the following Appendix, which is incorporated herein by this reference:
1. Appendix A: A detailed description of the system and its methods as a step-by-step process.

It will be understood that various details of the invention disclosed herein can be changed without departing from the scope of the subject matter disclosed herein. Furthermore, the foregoing description in Appendix A is for the purpose of illustration only, and not for the purpose of limitation.

### Appendix A: A Detailed Description of the System and its Methods as a Step-By-Step Process

Step-by-step methodology for the calibration of a physical zone using a numerical rating that indicates the potential of the physical zone to facilitate the health and/or healthy behavior of subjects inhabiting the said physical zone.

### A. Data Gathering Process

1. Create CAD files of all floorplans for a given building or physical zone.
2. Categorize rooms or spaces based on user type.
3. Connect rooms or spaces together using lines as paths.
4. Measure the length of each path made.
5. Create a unique identifier for each path.
6. Record each path's identifier, length, and elevation change in a spreadsheet.
7. Walk the length of each path and record the following using biosensing equipment such as a Fitbit wearable device:
Start and end step count.
   i. Is step data valid? Else, repeat the journey.
Start and end heart rate.
   i. Is heart rate data valid? Else, repeat the journey.
Start and end calorie expenditure.
   i. Is calorie data valid? Else, repeat the journey.
      8. Tabulate the data gathered for all the journeys in a spreadsheet using a format such as the one shown below in TABLE 1:

### B. Data Analysis Process

1. Determine probability score
a. Calculate the combinations for all possible journeys in the building or physical zone (nCr) for all floor and space combinations (n=total rooms, r=2 for individual segment journeys, 3-4 for composite journeys).
b. Calculate the combinations of all viable journeys (nCr) for all floor and space combinations, with n being total number of viable journey destination rooms or spaces.
c. Divide the sum of the viable journeys (nCr calculations) by the sum of the total journeys (nCr calculations) to arrive at the probability score.

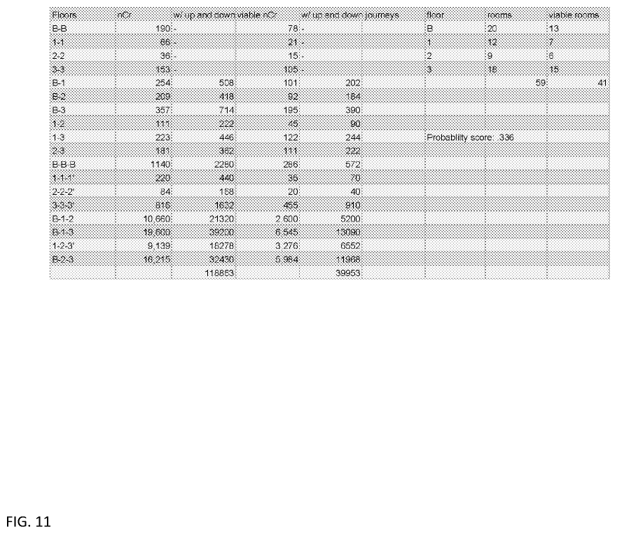

This process is illustrated in FIG. 11.

2. Determine magnitude scores
a. Compute combinations (nCr) for viable journeys for all floor and space combinations including composite journeys.
b. Multiply journeys between floors by two to account for paths up and down the stairs.
c. Calculate the sum of all combinations (nCr) for viable journeys in the building and multiply by:
   i. Average steps taken.
   ii. Average calories burned.
   iii. Average Heart Rate change.
d. Record the data in step c. for each data type (steps taken, calories burned, and heart rate change) as the Total Magnitude. Tabulate the data using a format such as the one shown below in TABLE 2.
e. Normalize the Total Magnitude by scaling it and reducing its order of magnitude to 10, making it a Magnitude Score out of 10.

TABLE 2

| | | Viable | Total | Magnitude |
|---|---|---|---|---|
| | Average | Journeys | Magnitude | Score |
| Steps Taken | 56.44230769 | 39,953 | 2255039.519 | 2.255039519 |
| Calories | 5.108974359 | 39,953 | 204118.8526 | 2.041188526 |
| Burned | | | | |
| Heart | 3.185897436 | 39,953 | 127286.1603 | 1.27286 |
| Rate | | | | |
| Change | | | | |

3. Determine the effectiveness score for each data type using a histogram-based rating.
a. Create histograms with three buckets based on the range of data for each data type.
b. Determine platinum, gold, or silver rating for each data type based on where the data falls in the buckets.

### C. Performance Rating Process

The final calibration of the physical zone with a numerical rating is made by summing and normalizing the score equivalents for the magnitudes, and the effectiveness based on the histograms.

1. Magnitudes: the three magnitude scores derived in the Data Analysis process are recorded.
2. Histogram-based Ratings: All the journeys for which data were recorded are classified using a histogram with three buckets based on the magnitudes of the data recorded for each type of data. Each bucket is given a label of silver, gold, and platinum from left to right. These labels are assigned the respective point values of 3.33, 6.66, and 10. Each histogram for a data type (e.g., steps taken, calories burned and heart rate change) is assigned one of these rating scores based on the bucket with the most data.
3. The Score Equivalents of the Magnitudes and the Histogram-based Ratings are tabulated using a format such as the one shown below in TABLE 3:

TABLE 3

| | | Score |
|---|---|---|
| | Data | Equivalent |
| Magnitudes | | |
| Total magnitude of steps taken | 2,255,040 | 2.26 |
| Total magnitude of calories burned | 204,119 | 2.04 |
| Total magnitude of Heart Rate | 127,286 | 1.28 |
| change | | |
| Histogram-based Ratings | | |
| Rating of steps taken | silver | 3.33 |
| Rating of calories burned | silver | 3.33 |
| Rating of Heart Rate change | silver | 3.33 |
| Final Calibration Rating | | 2.595 |

The final calibration in the form of a numerical rating for Klai Hall was found to be 2.595/10 in the example shown above.

### 4. Calculating the Final Calibration Rating

The final calibration of the physical zone as a numerical rating is made by taking the sum of the six scores in the Score Equivalent column in TABLE 3 above and dividing the sum by 60 (the number of different scores in the column (6) multiplied by 10) to normalize the final rating and make it out of 10.

1. A system comprising methods to calibrate a physical zone using a numerical rating to indicate the physical zone's potential for facilitating the health and/or healthy behavior of subjects inhabiting the physical zone using data gathered from the subjects with biosensing equipment. The system comprises:
a. A method comprising processes that are used to extract information about the physical features of the physical zone.
b. A method comprising processes that are used to measure the biophysical responses of subjects inhabiting the physical zone using biosensing equipment.
c. A method comprising processes that are used to analyze and process the data embodied in the measurements made with the biosensing equipment referenced in method b.
d. A method comprising processes that are used to calibrate the physical zone with a numerical rating, using the data referenced in method c.

2. Automated or partially automated implementations of the system and methods in claim 1.
